(19) United States
(12) Patent Application Publication
(10) Pub. No.: US 2011/0133247 A1
(43) Pub. Date: Jun. 9, 2011

(54) Zener-Triggered SCR-Based Electrostatic Discharge Protection Devices For CDM And HBM Stress Conditions

(76) Inventors: Hossein Sarbishaei, Kitchener (CA); Manoj Sachdev, Waterloo (CA)

(21) Appl. No.: 12/633,263

(22) Filed: Dec. 8, 2009

(51) Int. Cl. H01L 29/73; H01L 21/331

(52) U.S. Cl. 257/173; 438/133; 257/E29.181; 257/E21.37

(57) ABSTRACT

SCR device is modified to improve turn-on speed for CDM stress conditions. A zener diode is integrated inside SCR device to create an internal feedback and improve turn-on speed. The zener diode is designed as a p⁺n⁺ diode in the boundary of the well-substrate junction. In the preferred implementation, zener diode is integrated inside the DSCR and is called zener-triggered DSCR. Zener-triggered DSCR reduces the first breakdown voltage to provide protection for thin gate oxide during HBM stress conditions. At the same time, this device increases turn-on speed to provide protection for CDM stress conditions.

The present invention relates generally to Electrostatic Discharge (ESD) protection circuits. It specifically emphasizes on optimizing ESD protection devices for Charge Device Model (CDM) and Human Body Model (HBM) stresses. This application claims the benefit of priority of U.S. Provisional Patent Application No. 61/193,563 filed Dec. 8, 2008 which is incorporated herein by reference in its entirety.

### BACKGROUND

The objective of an on-chip ESD protection circuit is to create a harmless shunting path for the static electricity before it damages the sensitive electronic circuits. This objective becomes difficult as we shrink transistor geometries. In particular, reduced gate-oxide thickness and shallower junction depth makes devices more susceptible to ESD.

Researchers have observed disproportionate number of ESD related failures when System on Chips (SoCs) are stressed through CDM. The CDM assumes a charge on the conductive path of a chip is quickly (few nano-seconds) discharged through a pin into a low-ohmic ground. As apparent, the CDM stress current has much higher peak compared to that of Machine Model (MM) and HBM. FIG. 1 illustrates currents associated with various stresses as functions of time. In addition, the device and package capacitances and impedances play an important role on CDM performance. Finally, automated manufacturing is giving rise to higher percentage of CDM related failures.

Unfortunately, traditional ESD protection strategies which are effective against HBM and MM stresses generally are not effective against CDM stresses in nano-metric regime. First of all, in these technologies the damages (gate oxide, junction breakdown) will occur at lower voltages. Secondly, relatively slow ESD protection circuits are not able to trigger quickly enough to dissipate the ESD energy associated with CDM stress. Thirdly, larger, faster chips require complex packages that have higher capacitances for decoupling purposes which results in higher CDM discharge currents through the device.

Complete ESD protection for any chip is provided by adding ESD protection blocks to all I/O pins. FIG. 2 shows a general block diagram for a complete chip level ESD protection strategy. In this figure ESD_{D} provides ESD protection between I/O pad and V_{DD}, ESD_{S} provides protection between I/O pad and V_{SS}, and ESD_{C} provides protection between V_{DD} and V_{SS}. At the same time, these ESD protection blocks should have minimum impact on normal circuit behaviour. Specifically, for high speed I/Os, low leakage and minimum capacitance are the main requirements for ESD protection blocks. In CMOS technology, Metal Oxide Semiconductor Field Effect Transistor (MOSFET), Silicon Controlled Rectifier (SCR) and diode are the main devices that are used in ESD protection circuits.

Referring to FIG. 3(a), an SCR consists of two cross coupled bipolar transistors 300 and 305, well resistance R_{n-well} and substrate resistance R_{p-sub}. Cross section of SCR in CMOS technology, which is often referred to as lateral SCR, is shown in FIG. 3(b). SCR is fabricated in a substrate 310. Diffusion regions 320 and 325 inside n-well 315 form the anode of the device. Diffusion regions 330 and 335 in the substrate form the cathode. As an ESD protection device, anode is connected to the pad and cathode is connected to ground/V_{SS}. Triggering starts with avalanche breakdown of the well-substrate junction. Once triggered, both bipolar transistors, 300 and 305, are in saturation region, creating a very low resistive discharge path for ESD stress. However, as both bipolar devices should conduct in saturation mode turn-on speed of the device is relatively slow.

Silicon Controlled Rectifier (SCR) has the highest ESD protection level per unit area which makes it a promising choice for high speed applications. However, its first breakdown voltage is too high to provide protection for thin oxide devices. To reduce the first breakdown voltage of SCR, Darlington-based SCR (DSCR) is used which is shown in FIG. 4(a). Bipolar transistors 400 and 410, along with n-well and p-sub resistors form the original SCR. An additional bipolar transistor, 405 is added to form a Darlington pair with transistor 410. FIG. 4(b) depicts cross section of the DSCR. In this device the n-well 425 and the diffusion 450 are added to form the extra bipolar transistor. Diffusion 440 is placed in the boundary of the well 420 and substrate 415. Diffusion regions 430 and 435 form the anode and diffusion regions 445 and 455 form the cathode of the device. The value of the first breakdown voltage is a function of the spacing between the diffusion region 445 and the n-well 425, which is called “D”. Reducing “D” reduces the first breakdown voltage. At the same time, very small values of “D” results in high leakage current under normal operating conditions.

In addition to high first breakdown voltage, SCR devices suffer from slow turn-on speed, especially under very fast ESD stress conditions such as CDM. Even though the DSCR provides an effective solution against HBM, the turn-on speed of the DSCR is not very high on order to provide an effective ESD solution against CDM stress. As a result, it's necessary to design a new device that has a low first breakdown voltage with a fast turn-on speed.

### SUMMARY OF THE INVENTION

In accordance with an aspect of the present invention there is provided a new method to improve turn-on speed of SCR-based devices under CDM stress conditions. The method adds an internal feedback with a zener diode to improve turn-on speed of the SCR device. Adding the zener diode to DSCR creates a device with low first breakdown voltage, fast turn-on time and small capacitance.

### BRIEF DESCRIPTION OF THE DRAWINGS

Embodiments of the present invention will now be described with reference to the following drawings in which:

FIG. 1 compares discharge current of different ESD stresses;

FIG. 2 is the block diagram of the ESD protection strategy;

FIG. 3(a) is the equivalent circuit of an SCR (prior art);

FIG. 3(b) is the cross section of an SCR device in Complementary Metal Oxide Semiconductor (CMOS) technology (prior art);

FIG. 4(a) is equivalent circuit of the Darlington-based SCR (DSCR) device (prior art);

FIG. 4(b) is the cross section of the Darlington-based SCR (DSCR) device (prior art);

FIG. 5 is the equivalent circuit of the zener-triggered SCR;

FIG. 6 is the cross section of the zener-triggered SCR;

FIG. 7 is the cross section of the zener-triggered DSCR in accordance with an alternate embodiment;

FIG. 8 is the cross section of the improved zener-triggered DSCR in accordance with an alternate embodiment;

FIG. 9 is the simulated I-V characteristic of the zener-triggered DSCR in FIG. 8;

FIG. 10 is the simulated CDM response of the zener-triggered DSCR in FIG. 8;

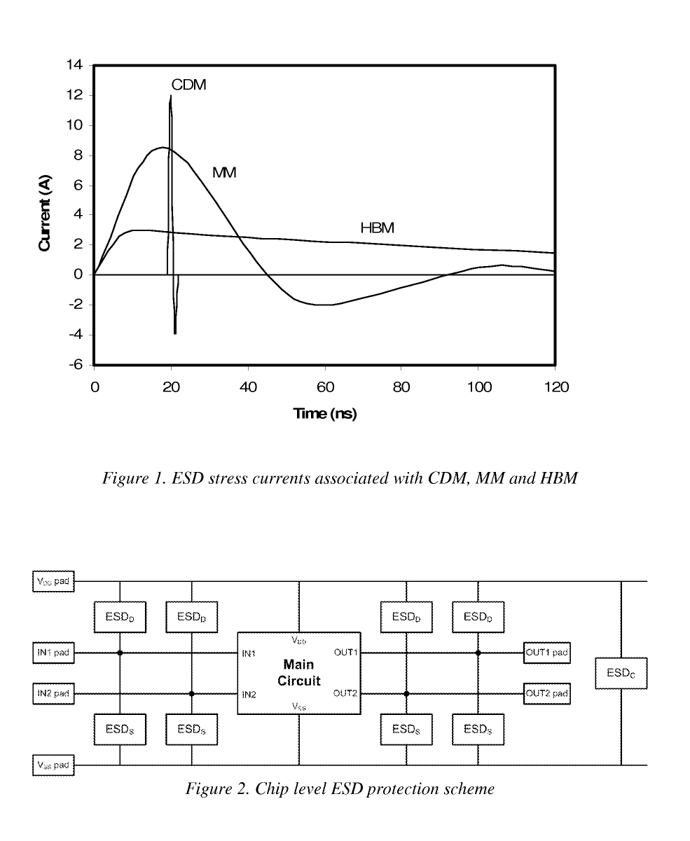

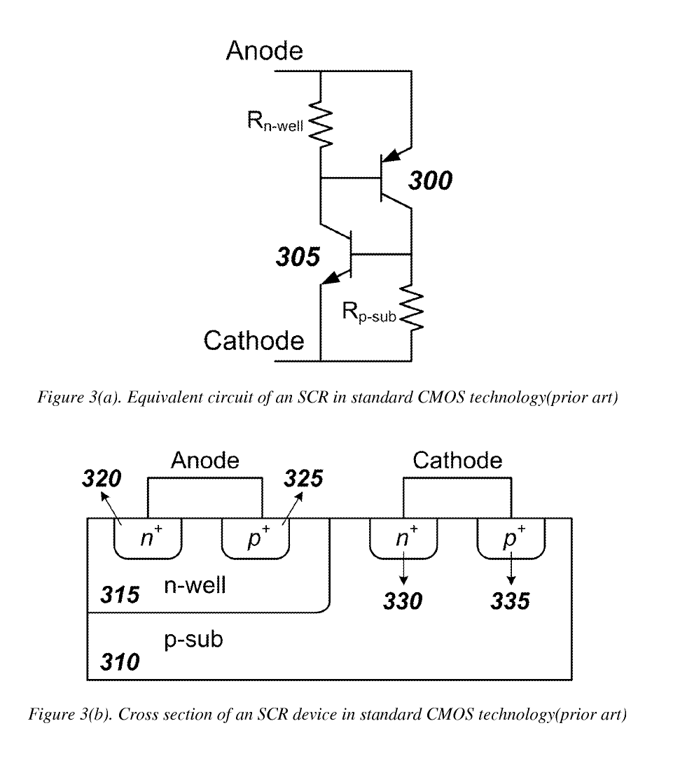

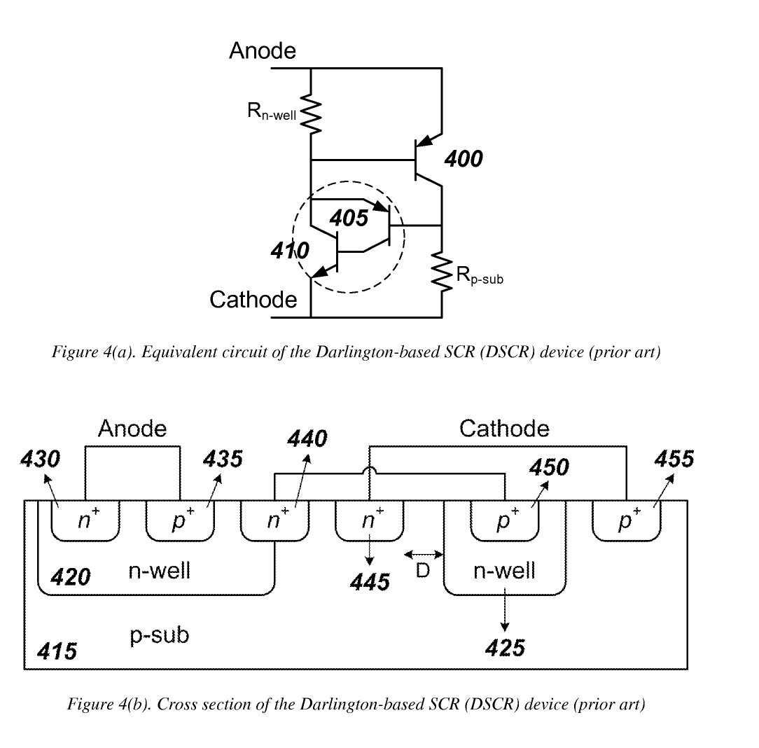

### DETAILED DESCRIPTION OF THE PREFERRED EMBODIMENTS

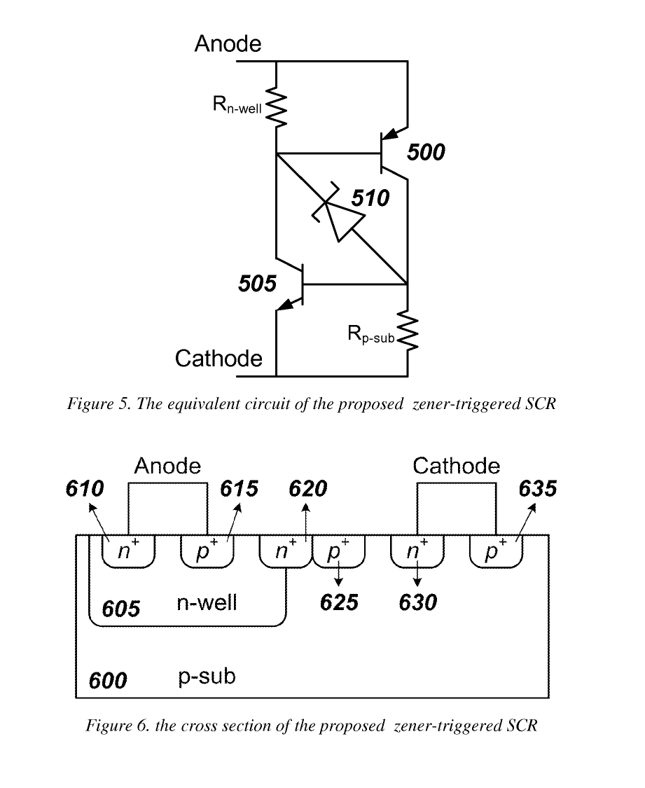

Referring to FIG. 5, equivalent circuit of a zener triggered SCR in accordance with an embodiment of the invention is illustrated. The pnp transistor 500 and the npn transistor 505 along with n-well and p-sub resistors form the SCR device. Emitter of the pnp transistor 500 is connected to the anode. Emitter of the npn transistor 505 is connected to the cathode. Base of the pnp transistor 500 is connected to collector of the npn transistor 505. Based of the npn transistor 505 is connected to collector of the pnp transistor 500. An extra feedback is added inside the SCR to speed up turn-on time of the SCR. This feedback is provided using a zener diode 510 and is integrated inside SCR structure. The zener diode 510 is placed between base of the pnp transistor 500 and base of the npn transistor 505.

Zener diode is created by placing an n⁺ region beside a p⁺ region to form an n⁺p⁺ diode. In CMOS technology a silicide-block mask is required to avoid a short circuit between two diode nodes. FIG. 6 depicts the cross section of a first embodiment zener triggered SCR. Similar to the conventional SCR, this device is fabricated in the substrate 600. The n⁺ diffusion region 610 and the p⁺ diffusion region 615 are placed in the n-well 605 and are connected to each other to form the anode. The n⁺ diffusion region 630 and the p⁺ diffusion region 635 are placed in the substrate 600 and are connected to each other to form the cathode. The zener diode is integrated in the SCR structure by adding the n⁺ diffusion region 620 and the p⁺ diffusion region 625.

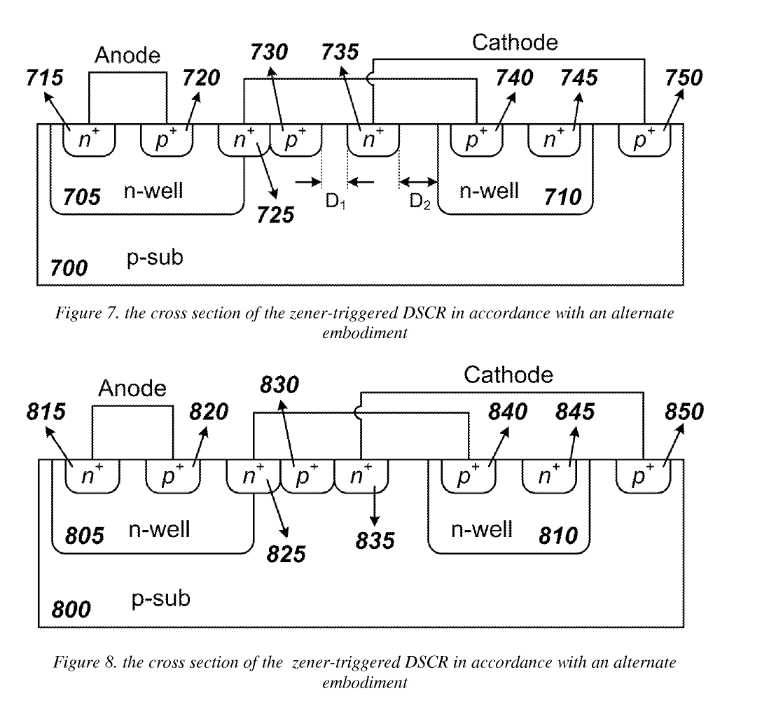

FIG. 7 shows the cross section of the second embodiment of zener-triggered device. In this configuration, zener triggering is applied to the DSCR device. The n⁺ diffusion region 715 and the p⁺ diffusion region 720 are connected to each other to form the anode of the device. The n⁺ diffusion region 735 and the p⁺ diffusion region 750 are connected to each other to form the cathode. The extra pnp transistor is created by the n-well 710 and the p⁺ diffusion 740. The zener diode is formed by the n⁺ diffusion region 725 and the p⁺ diffusion region 730. The spacing between the n⁺ diffusion 735 and the n-well 710, which is called D₂, sets the first breakdown voltage of the device. Reducing D₂ reduces the first breakdown voltage. At the same time, very small D₂ increases leakage of the device under normal operating conditions. The spacing between p⁺ diffusion 730 and n⁺ diffusion 735, which is called D₁, sets the turn-on time of the device. Reducing D₁ increases turn-on speed of the device with small impact on the first breakdown voltage.

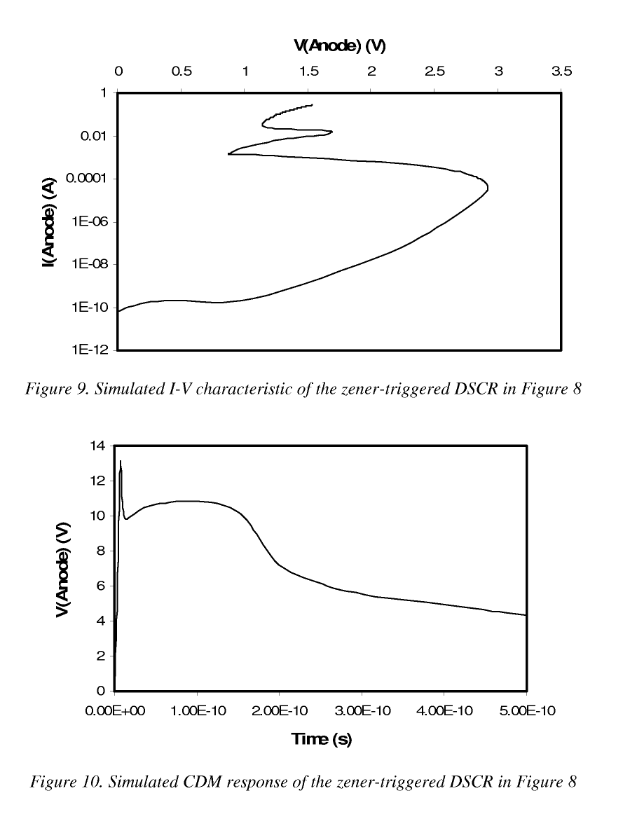

In the preferred embodiment, the spacing between regions 730 and 735, D₁, is reduced to zero. FIG. 8 shows the cross section of this device. This device has the fastest turn-on speed and maintains similar first breakdown voltage and leakage under normal operating conditions.

FIG. 9 shows simulated I-V characteristic for the preferred embodiment of FIG. 8. Simulation is done using Medici device simulator. The device is designed and simulated in 90 nm CMOS technology. The first breakdown voltage of this device is 2.9V. This value is low enough to provide protection in 90 nm technology.

FIG. 10 shows simulated CDM response for the preferred embodiment of FIG. 8. A 500V CDM response is applied to the zener-triggered DSCR and the voltage drop between anode and cathode is simulated. Maximum anode voltage during CDM determines turn-on speed of the device. This voltage is 13V for zener-triggered DSCR and is 8V smaller than the original DSCR.

1. A Silicon Controlled Rectifier based ESD device comprising steps of:
Starting with a semiconductor substrate with a certain doping type;
Forming the well region in the substrate with opposite doping to the substrate;
Forming two doped regions in the well, first region with the same doping as the well, second region opposite doping to the well;
Forming the third doped region at the boundary of the well and substrate with the same doping as the well;
Forming the fourth doped region contiguous to the third doped region with opposite doping to the third doped region;
Forming the fifth doped region in the substrate with doping opposite to the substrate and placed with a finite space from the fourth doped region;
Forming the sixth doped region in the substrate with the same doping as the substrate;

2. ESD protection device of claim 1 where first and second doped regions are connected to each other to form anode of the device.

3. ESD protection device of claim 1 where fifth and sixth doped regions are connected to each other to form cathode of the device.

4. A Silicon Controlled Rectifier based ESD device comprising steps of:
Starting with a semiconductor substrate with a certain doping type;
Forming the first well region in the substrate with opposite doping to substrate;
Forming the second well region in substrate and spaced from the first well with opposite doping to substrate;
Forming two doped regions in the first well, first region the same doping as the well, second region opposite doping to the well;
Forming the third doped region in the boundary of the first well and substrate with the same doping as the first well;
Forming the fourth doped region beside the third doped region with opposite doping to the third doped region;
Forming the fifth doped region between the fourth doped region and the second well with the same doping as the second well;
Forming sixth and seventh doped regions in the second well, sixth region doped opposite to the second well and seventh region doped the same as the second well;
Forming the eighth doped region in the substrate and after the second well with the same doping as the substrate;

5. ESD protection device of claim 4 where first and second doped regions are connected to each other to form anode of the device.

6. ESD protection device of claim 4 where fifth and eighth doped regions are connected to each other to form cathode of the device.

7. ESD protection device of claim 4 where third and sixth doped regions are connected to each other.

8. ESD protection device of claim 4 where the spacing between fourth and fifth doped regions is reduced to zero to maximize turn-on speed of the device.
